(19) United States
(12) Patent Application Publication
(10) Pub. No.: US 2024/0194547 A1
(43) Pub. Date: Jun. 13, 2024

(54) SUBSTRATES FOR SEMICONDUCTOR PACKAGES

(71) Applicant: Micron Technology, Inc., Boise, ID (US)

(72) Inventors: Ling Pan, Singapore (SG); Seng Kim Ye, Singapore (SG); Hong Wan Ng, Singapore (SG); Kelvin Aik Boo Tan, Singapore (SG); See Hiong Leow, Singapore (SG)

(21) Appl. No.: 18/517,980

(22) Filed: Nov. 22, 2023

Related U.S. Application Data
(60) Provisional application No. 63/432,226, filed on Dec. 13, 2022.

(51) Int. Cl. H01L 23/13; H01L 21/48; H01L 23/00; H01L 23/498; H01L 25/18; H10B 80/00

(52) U.S. Cl. CPC H01L 23/13; H01L 21/4857; H01L 23/49822; H01L 23/49827; H01L 23/49894; H01L 24/48; H01L 25/18; H10B 80/00; H01L 24/16; H01L 24/32; H01L 24/33; H01L 24/73; H01L 2224/16227; H01L 2224/32145; H01L 2224/32225; H01L 2224/33181; H01L 2224/48091; H01L 2224/48227; H01L 2224/73253; H01L 2224/73265

(57) ABSTRACT

A variety of applications can include systems having packaged electronic devices. One or more of the packaged electronic devices can include a package substrate, having a first section and a second section with the second section elevated with respect to the first section, to support dies in the two sections. The first section can have a first top surface and a bottom surface with one or more layers of material between the first top surface and the bottom surface. The second section can include a second top surface and the bottom surface of the first section with the one or more layers of material of the first section extending horizontally from the first section. The second section can have one or more additional layers of material between the second top surface and the one or more layers of material of the first section extending horizontally from the first section.

### PRIORITY APPLICATION

This application claims the benefit of priority to U.S. Provisional Application Ser. No. 63/432,226, filed 13 Dec. 2022, which is incorporated herein by reference in its entirety.

### FIELD OF THE DISCLOSURE

Embodiments of the disclosure relate generally to electronic devices and, more specifically, to structures for semiconductor packages and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Operation and properties of memory devices and other electronic devices can be improved by enhancements to the design of packaging of electronic devices such as, but not limited to, semiconductor packages for multiple dies.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a cross-sectional representation of a packaged electronic device having multiple dies.

FIG. 2 is a cross-sectional representation of an example package substrate to support multiple dies, according to various embodiments.

FIG. 3 is a cross-sectional representation of another example package substrate to support multiple dies, according to various embodiments.

FIG. 4 is a cross-sectional representation of an example packaged electronic device having multiple dies, according to various embodiments.

FIG. 5 is a cross-sectional representation of another example packaged electronic device having multiple dies, according to various embodiments.

FIG. 6 is a block diagram of an example system having one or more example packaged electronic devices, according to various embodiments.

FIG. 7 is a flow diagram of features of an example method of forming a package substrate to support multiple dies, according to various embodiments.

FIG. 8 is a flow diagram of features of another example method of forming a package substrate to support multiple dies, according to various embodiments.

FIG. 9 illustrates a block diagram of an example machine including one or more packaged electronic devices, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments can be utilized, and structural, logical, mechanical, and electrical changes can be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

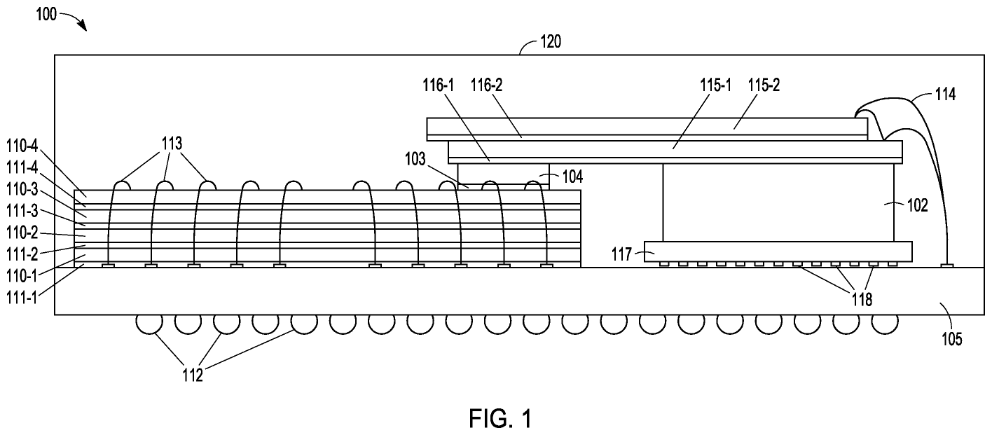

FIG. 1 is a cross-sectional representation of a packaged electronic device 100 having multiple dies supported by a package substrate 105. Dies 110-1, 110-2, 110-3, and 110-4 form one set of dies and dies 115-1, 115-2, and 117 form a second set of dies, where the two sets of dies are arranged for initial support on different portions of package substrate 105. Die 110-4 can be separated from die 110-3 by a region 111-4. Die 110-3 can be separated from die 110-2 by a region 111-3. Die 110-2 can be separated from die 110-1 by a region 111-2. Die 110-1 can be separated from package substrate 105 by a region 111-1. Each of regions 111-1, 111-2, 111-3, and 111-4 can include a backing of the respective die, an adhesive, or a paste, among other materials. Die 115-2 can be separated from die 115-1 by a region 116-2. Die 115-1 can be separated from a spacer 102 by a region 116-1. Each of regions 116-1 and 116-2 can include a backing of the respective die, an adhesive, or a paste, among other materials. Spacer 102 can separate die 115-1 from die 117, where die 117 is coupled to package substrate 105 by contacts 118. Contacts 118 can be, but are not limited to, a ball grid array.

Dies 115-1 and 115-2 can be arranged with a support on a different region of package substrate 105 than the support for dies 110-1, 110-2, 110-3, and 110-4. With dies 115-2 and 115-1 also arranged above dies 110-1, 110-2, 110-3, and 110-4, a spacer 104 is used between die 115-1 and die 110-4. Die 115-1 can be separated from spacer 104 also by region 116-1 and spacer 104 can be separated from die 110-4 by a region 103. Region 103 can include a backing of spacer 104, an adhesive, or a paste, among other materials. Spacers 102 and 104 provide a mechanism for two sets of dies to be structured within a packaged electronic device 100 such that the dies can be arranged in a level manner, that is, the dies can be arranged parallel to package substrate 105.

Dies 110-1, 110-2, 110-3, and 110-4 can be the same type of device and can be different from the type of devices implemented in dies 115-1, 115-2, and 117. In a non-limiting example, dies 110-1, 110-2, 110-3, and 110-4 can be DRAM dies and dies 115-1 and 115-2 can be NAND memory dies, where die 117 can be a controller die. Since different die types are implemented in packaged electronic device 100, it may not the appropriate to arrange all the dies in a common stack. As shown in FIG. 1, spacers 102 and 104 are implemented to arrange the different types of dies within the dimensions of the inner section of packaged electronic device 100. Typically, spacer 102 and spacer 104 are silicon spacers. However, use of relatively thick silicon spacers can undesirably increase part or production costs. With spacer 104 and spacer 102 being silicon spacers different from the materials of the dies, wires, and package substrate 105, there can be an issue of a mismatch of thermal properties within packaged electronic device 100. This thermal issue can be apparent by a mismatch of the coefficient of thermal expansion (CTE) of spacers 102 and 104 with respect to the other components within packaged electronic device 100. CTE values of different features in the package differ and cause mismatches. Active dies and spacers are typically made of silicon, which is a significantly low CTE material, while the CTE value of other materials in package are much higher than silicon. When such a package goes through high temperature operations or temperature cycling, silicon can shrink or expand to levels different from the other non-silicon material, which can cause stress and strain in coupling of these materials in the package such as packaged electronic device 100. For example, the CTE of a spacer is higher than the CTE of mold compound. In some cases, warpage can become out of specification limits due to high shrinkage of mold compound when there is excessive mold compound volume. The CTE mismatch can result in warpage of the dies within packaged electronic device 100, which can reduce the reliability performance of the dies within packaged electronic device 100.

The components of packaged electronic device 100 can be encapsulated with a mold compound 120. This encapsulation includes encapsulation of bond wires to the dies within packaged electronic device 100. Die 110-4 can be coupled to package substrate 105 by a set of wires 113. Dies 110-1, 110-2, and 110-3 can also be coupled to package substrate 105 by wires. Dies 115-1 and 115-2 can be coupled to package substrate 105 by a set of wires 114. The set of wires 114 can be substantially longer than the set of wires 113. The longer wires can be susceptible to wire sweep, where wire sweep is a deformation that can occur when bonded wires are not correctly aligned in the horizontal plane. Wire sweep is undesirable, as it can affect electrical performance by changing the mutual inductance of adjacent wires. Wire sweep can occur during forming of mold compound 120. A mismatch associated with spacer 102 being relatively large and the dies having varying die size aspect ratios (width to length) within packaged electronic device 100 can result in a relatively large mold compound volume that can lead to wire sweep risk due to one or more long wires of the set of wires 114 to the top of die 115-2, which is at the top of a die stack. Such a relatively large mold compound can also lead to excessive mold compound volume, which can be a source of high positive warpage, relative to specifications, of dies such as at 260° C. for current design layouts, for example, as shown in FIG. 1.

Package substrate 105 has contacts 112 to allow components of packaged electronic device 100 to communicate, through package substrate 105, with electronic devices or systems exterior to packaged electronic device 100. Contacts 112 can be implemented by a ball grid array or other arrangements of contacts.

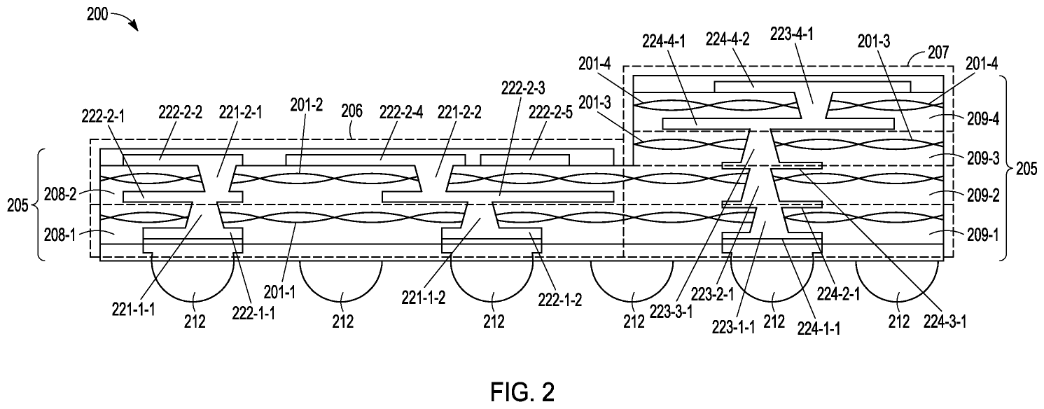

FIG. 2 is a cross-sectional representation of an embodiment of an architecture 200 having an exemplary package substrate 205 to support multiple dies. A package substrate is a substrate that can be implemented in a package for an electronic device to hold components of the electronic device. Package substrate 205 can be structured with a side portion elevated, with respect to another side portion of package substrate 205, to provide support to a set of one or more top dies of stacked dies. The structure of package substrate 205 provides a mechanism that effectively replaces use of a spacer such as spacer 102 of FIG. 1. Package substrate 205 can be structured with two sections, section 206 and section 207. Though package substrate 205 shows one section (section 207) elevated with respect to section (section 206), package substrate 205 can be implemented with more than one section elevated with respect to the one section (section 206). Though two sections are shown in FIG. 2, a package substrate, similar to package substrate 205, can be structured with more than two sections with each section having a top surface sufficiently planar in the horizontal direction to provide some support for dies positioned in the respective section of the package substrate.

Section 206 contains a layer 208-1 and a layer 208-2, where each layer of section 206 is oriented in a horizontal direction. Layers 208-1 and 208-2 can be formed as a laminate, in a serial manner, with layer 208-2 formed on layer 208-1. Layer 208-1 can include a reinforcement fiber 201-1 and layer 208-2 can include a reinforcement fiber 201-2.

Section 207 contains a layer 209-1, a layer 209-2, a layer 209-3, and a layer 209-4, where each layer of section 207 is oriented in a horizontal direction. Layers 209-1, 209-2, 209-3, and 209-4 can be formed as a laminate, in a serial manner, with layer 209-4 formed on layer 209-3, layer 209-3 formed on layer 209-2, and layer 209-2 formed on layer 209-1. Layer 209-4 can include a reinforcement fiber 201-4 and layer 209-3 can include a reinforcement fiber 201-3. Layer 209-2 of section 207 can be realized as layer 208-2 extending horizontally from section 206 and layer 209-1 of section 207 can be realized as layer 208-1 extending horizontally from section 206. As extensions of layers from section 206, layer 209-2 can contain reinforcement fiber 201-2 and layer 209-2 can contain reinforcement fiber 201-1. Alternatively, layers 209-1 and 209-2 can be fabricated separately from layers 208-1 and 208-2 with layers 209-1 and 209-2 and layers 208-1 and 208-2 having the same material connected together with top and bottom surfaces aligned. In such an alternative fabrication approach, layers 209-1 and 209-2 can be structured with different reinforcement fibers than the reinforcement fibers of layers 208-1 and 209-2. Though section 206 is shown in FIG. 2 having two layers between a top surface of section 206 and a bottom surface of section 206, section 206 can have more or fewer than two layers between the top surface of section 206 and the bottom surface of section 206. Though section 207 is shown in FIG. 2 having four layers between a top surface of section 207 and a bottom surface of section 207, section 207 can have more or fewer than four layers between the top surface of section 207 and the bottom surface of section 207, with section 207 having at least one more layer than section 206.

The layers of sections 206 and 207 can be fabricated having common material and structure in each layer. Material of each layer can be selected from a number of different compositions. One or more of the layers of sections 206 and 207 can include a halogen-free bismaleimide triazine resin material. The layers of sections 206 and 207, using material similar to bismaleimide triazine resin material, can be patterned to provide routing circuitry in sections 206 and 207. Section 206 can have fewer signal routing layers than signal routing layers of section 207. One or more of the layers of sections 206 and 207 can include a metal-clad laminate with metal cladding of the metal-clad laminate patterned with conductive routing. The metal-clad laminate can be a copper-clad laminate. The laminate can be structured using a reinforcing fiber impregnated with resin. The reinforcing fiber can be, but is not limited to, fiberglass. A metal cladding formed on surfaces of the processed fiber and resin can be patterned to provide routing circuitry in the layers of sections 206 and 207.

The bottom surface of package substrate 205 can have multiple contacts 212 to communicate with other devices or systems from dies to be placed on package substrate 205. Contacts 212 can be, but are not limited to, a ball grid array. A pad 222-1-1 can be formed in layer 208-1 of section 206 at a contact 212 to provide signal routing at a level associated with layer 208-1, which can include signal routing extending into layer 209-1 of section 207. Vias can be structured in package substrate 205 as through-chip vias, which can be referred to as through-silicon vias (TSVs), where such vias can provide one or more vertical electrical connections that can pass completely through a wafer, a die, a substrate, or a substrate layer, depending on the structure in which the via is formed. A via 221-1-1 can be formed to couple pad 222-1-1 of layer 208-1 to a pad 222-2-1 in layer 208-2 of section 206. Pad 222-2-1 can be structured to provide signal routing at a level associated with layer 208-2 at an interface with layer 208-1, which can include signal routing extending into layer 209-2 of section 207. A via 221-2-1 can be formed to couple pad 222-2-1 of layer 208-2 to a pad 222-2-2 in layer 208-2 of section 206. Pad 222-2-2 can be structured to provide signal routing at a level associated with layer 208-2 of section 206, which can include signal routing extending into layer 209-2 of section 207.

A pad 222-1-2 can be formed in layer 208-1 of section 206 at a contact 212 to provide signal routing at a level associated with layer 208-1, which can include signal routing extending into layer 209-1 of section 207. A via 221-1-2 can be formed to couple pad 222-1-2 of layer 208-1 to a pad 222-2-3 in layer 208-2 of section 206. Pad 222-2-3 can be structured to provide signal routing at a level associated with layer 208-2 at an interface with layer 208-1, which can include signal routing extending into layer 209-2 of section 207. A via 221-2-2 can be formed to couple pad 222-2-3 of layer 208-2 to a pad 222-2-4 in layer 208-2 of section 206. Pad 222-2-4 can be structured to provide signal routing at a level associated with layer 208-2 of section 206, which can include signal routing extending into layer 209-2 of section 207. The layers of section 206 can include other conductive structures to provide signal routing in section 206, for example, but not limited to, pad 222-2-5.

A pad 224-1-1 can be formed in layer 209-1 of section 207 at a contact 212 to provide signal routing at a level associated with layer 209-1, which can include signal routing extending into layer 208-1 of section 206. A via 223-1-1 can be formed to couple pad 224-1-1 of layer 209-1 to a pad 224-2-1 in layer 209-2 of section 207. Pad 224-2-1 can be structured to provide signal routing at a level associated with layer 209-2 at an interface with layer 209-1, which can include signal routing extending into layer 208-2 of section 206. A via 223-2-1 can be formed to couple pad 224-2-1 of layer 209-2 to a pad 224-3-1 in layer 209-3 of section 207. Pad 224-3-1 can be structured to provide signal routing at a level associated with layer 209-3 of section 207 at an interface with layer 209-2.

A via 223-3-1 can be formed to couple pad 224-3-1 of layer 209-3 to a pad 224-4-1 in layer 209-4 of section 207. Pad 224-4-1 can be structured to provide signal routing at a level associated with layer 209-4 at an interface with layer 209-3. A via 223-4-1 can be formed to couple pad 224-4-1 of layer 209-4 to a pad 224-4-2 in layer 209-4 about the top of section 207. Pad 224-4-2 can be structured to provide signal routing at a level associated with layer 209-4 of section 207. The layers of section 207 can include other pads to provide signal routing in section 207. Section 207 can be structured having more signal routing layers than section 206.

With FIG. 2 being a cross-sectional view, other vias and landing pads to these vias are coupled to other of the contacts 212 providing communication paths to other sections of package substrate 205. These vias, pads, and contacts can be designed in number and location based on electronic dies to be positioned on package substrate 205. The contacts to mate with electrical communication paths exterior to package substrate 205 can be formed to meet designs associated with specifications for application of the electronic dies to be packaged on package substrate 205.

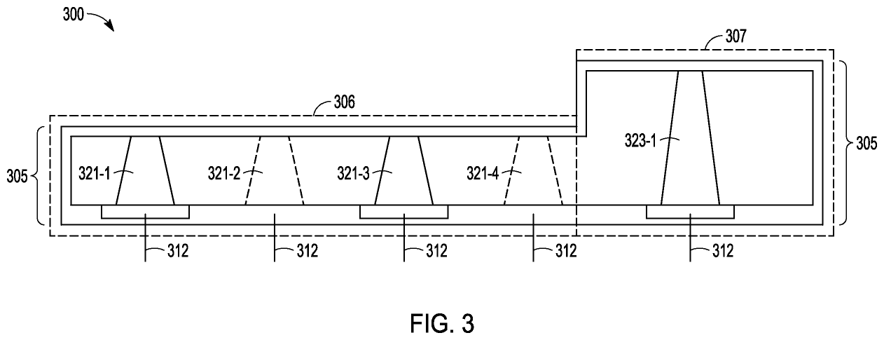

FIG. 3 is a cross-sectional representation of another embodiment of an architecture 300 having an example package substrate 305 to support multiple dies. Package substrate 305 can be structured with a side portion elevated, with respect to another side portion of package substrate 305, to provide support to a set of one or more top dies of stacked dies. The structure of package substrate 305 provides a mechanism that effectively replaces use of a spacer such as spacer 102 of FIG. 1 and can effectively replace use of a spacer such as spacer 104 of FIG. 1. Package substrate 305 can be structured with a section 307 elevated, with respect to another section 306 of package substrate 305, to provide support to a set of one or more top dies of stacked dies. Though package substrate 305 shows one section (section 307) elevated with respect to section (section 306), package substrate 305 can be implemented with more than one section elevated with respect to the one section (section 306). Though two sections are shown in FIG. 3, a package substrate, similar to package substrate 305, can be structured with more than two sections with each section having a top surface sufficiently planar in the horizontal direction to provide some support for dies positioned in the respective section of the package substrate.

Package substrate 305 can be structured as a substrate formed as a single entity having contacts 312 to provide communication paths for electronic dies to be placed on package substrate 305 to other electronic entities that will be exterior to package substrate 305. Vias 321-1, 321-2, 321-3, and 321-4 can be formed through package substrate 305 to contacts 312 in a section 306, and via 323-1 can be formed through package substrate 305 to contacts 312 in elevated section 307. The vias can be formed through the single entity using a drilling process such as using a laser. Though section 306 is shown in FIG. 3 having four vias between a top surface of section 306 and a bottom surface of section 306, section 306 can have more or fewer than four vias between the top surface of section 306 and the bottom surface of section 306. Though section 307 is shown in FIG. 3 having one via between a top surface of section 307 and a bottom surface of section 307, section 307 can have more than one via between the top surface of section 307 and the bottom surface of section 307. These vias allow for electrical connections from the bottom of package substrate 305 to a top of package substrate 305.

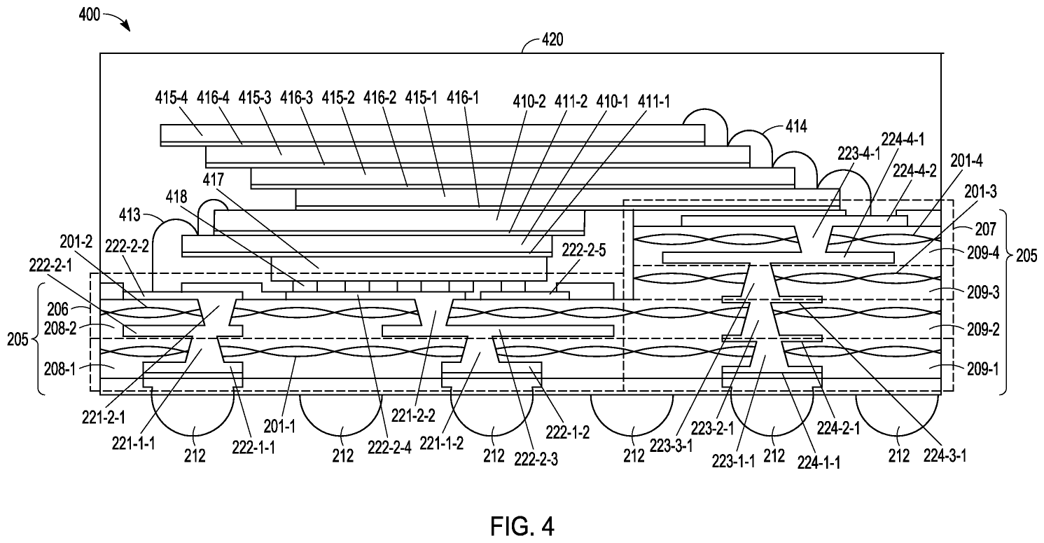

FIG. 4 is a cross-sectional representation of an embodiment of an example packaged electronic device 400 having multiple dies. Packaged electronic device 400 can include the multiple dies segregated into two sets with one set supported on a side portion of a package substrate elevated with respect to another side portion of the package substrate. Packaged electronic device 400 can be implemented using package substrate 205 and components of package substrate 205 of FIG. 2. Other multiple-section package substrates having one or more elevated sections, similar to package substrate 205, can be implemented.

Packaged electronic device 400 can include package substrate 205 to support multiple dies. Dies 410-1 and 410-2 and die 417 form one set of dies and dies 415-1, 415-2, 415-3, and 415-4 form a second set of dies, where the two sets of dies are arranged for initial support on different portions of package substrate 205. Die 410-2 can be separated from die 410-1 by a region 411-2. Die 410-1 can be separated from die 417 by a region 411-1. Each of regions 411-1 and 411-2 can be a backing of the respective die, an adhesive, or a paste. Die 417 can be positioned above a top surface of section 206 of package substrate 205 by contacts 418. Contacts 418 can be, but are not limited to, a ball grid array.

Die 415-4 can be separated from die 415-3 by a region 416-4. Die 415-3 can be separated from die 415-2 by a region 416-3. Die 415-2 can be separated from die 415-1 by a region 416-2. Die 415-1 can be separated from a top surface of section 207 of package substrate 205 by a region 416-1. Die 415-1 can also be positioned above die 410-2 and separated by a region aligned with region 416-1. Each of regions 416-1, 416-2, 416-3 and 416-4 can be a backing of the respective die, an adhesive, or a paste. The bottom surface of package substrate 205 in both section 206 and section 207 can include contacts 212 extending out from the bottom surface of package substrate 205. Contacts 212 can be, but are not limited to, a ball grid array.

Dies 415-1, 415-2, 415-3, and 415-4 can be arranged for support on a different region of package substrate 205 than the support for dies 410-1, 410-2, and 417. The two sets of dies within packaged electronic device 400 can be arranged in a level manner, that is, the dies can be arranged parallel to package substrate 205. Dies 410-1 and 410-2 can be the same type of device that can be, but is not limited to, different from the type of devices implemented in dies 415-1, 415-2, 415-3, 415-4, and 417. In a non-limiting example, dies 410-1 and 410-2 can be DRAM dies and dies 415-1, 415-2, 415-3, and 415-4 can be NAND memory dies, where die 417 can be a controller die. Such an arrangement forms a controller plus DRAM plus NAND memory device. Communication between the dies of packaged electronic device 400 can include use of conductive routing within package substrate 205. As shown in FIG. 4, the top surface of section 207 being elevated from the top surface of section 206 allows the arrangement of the different types of dies within the dimensions of the inner section of packaged electronic device 400.

The components of packaged electronic device 400 can be encapsulated with a mold compound 420. This encapsulation includes encapsulation of wires to the dies within packaged electronic device 400. Dies 410-2 and dies 410-1 can be coupled to package substrate 205 by a set of wires 413. Dies 415-1, 415-2, 415-3, and 415-4 can be coupled to package substrate 205 by a set of wires 414. The set of wires 414 can be have a length similar to the length of the set of wires 413. Contacts 212 of package substrate 205 can allow components of packaged electronic device 400 to communicate, through package substrate 205, with electronic devices or systems exterior to packaged electronic device 400.

As can be seen in comparing FIG. 4 with FIG. 1, package substrate 205 can provide additional characteristics not provided by package substrate 105. Package substrate 205 with a side portion that is elevated to provide support to a top stack of dies of packaged electronic device 400 can eliminate use of a costly and relatively thick silicon spacer (thick relative to the dies housed in packaged electronic devices). Such elimination can reduce the number of components in packaged electronic device 400. A package substrate, such as package substrate 205, can enhance reliability performance by reducing CTE mismatch within packaged electronic device 400. For example, package substrate 205 can reduce mold compound volume, by removing the use of spacers, which can help reduce shrinkage differences to balance warpage behavior when packaged electronic device 400 is in a relatively high temperature range. As seen in FIG. 4, package substrate 205 can allow for shorter wire length that can save cost as well as provide shorter signal path. The wires can be, but are not limited to, gold wires. Package substrate 205 can also reduce wire sweep risk due to long wires on the die stack extending to the top region of packaged electronic device 400.

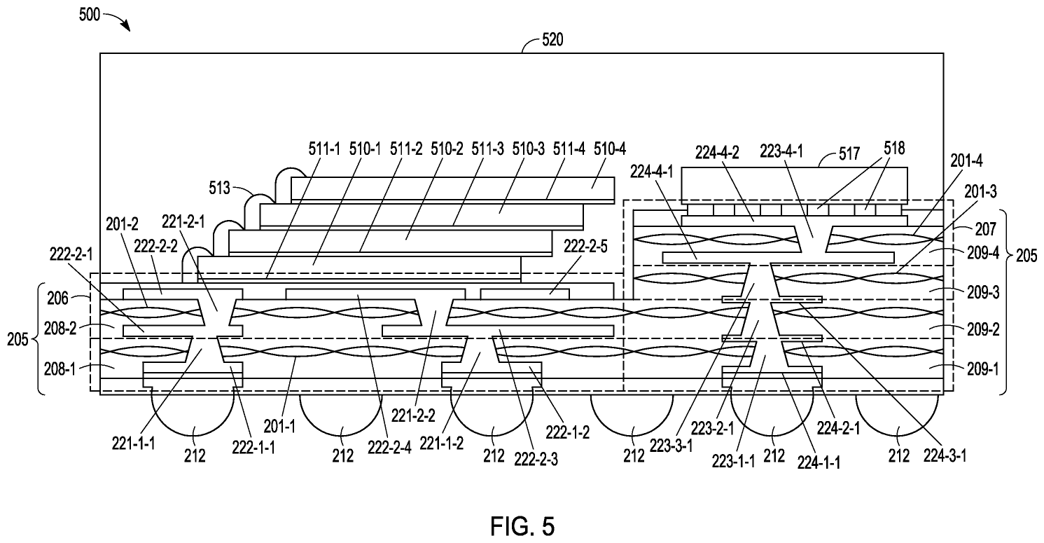

FIG. 5 is a cross-sectional representation of an embodiment of an example packaged electronic device 500 having multiple dies. Packaged electronic device 500 can include the multiple dies segregated into two sets with one set supported on a side of a package substrate elevated with respect to another side of the package substrate. Packaged electronic device 500 can be implemented using package substrate 205 and components of package substrate 205 of FIG. 2. Other multiple-section package substrates having one or more elevated sections, similar to package substrate 205, can be implemented.

Packaged electronic device 500 can include package substrate 205 to support multiple dies. Dies 510-1, 510-2, 510-3, and 510-4 form one set of dies and die 517 forms a second set of dies, where the two sets of dies are arranged for initial support on different portions of package substrate 205. Die 510-4 can be separated from die 510-3 by a region 511-4. Die 510-3 can be separated from die 510-2 by a region 511-3. Die 510-2 can be separated from die 510-1 by a region 511-2. Die 510-1 can be separated from the top surface of section 506 of package substrate 205 by a region 511-1. Each of regions 511-1, 511-2, 511-3, and 511-4 can be a backing of the respective die, an adhesive, or a paste. Die 517 can be positioned above a top surface of section 207 of package substrate 205 by contacts 518. Contacts 518 can be, but are not limited to, a ball grid array.

Dies 510-1, 510-2, 510-3, and 510-4 can be arranged for support on a different region of package substrate 205 than the support for die 517. The two sets of dies within packaged electronic device 500 can be arranged in a level manner, that is, the dies can be arranged parallel to package substrate 205. Dies 510-1, 510-2, 510-3, and 510-4 can be the same type of device that can be, but is not limited to, different from the type of devices implemented in die 517. In a non-limiting example, dies 510-1, 510-2, 510-3, and 510-4 can be NAND memory dies, where die 517 can be a controller die. Such an arrangement forms a controller plus NAND memory device, which can be part of a managed NAND memory system. Communication between the dies of packaged electronic device 500 can include use of conductive routing within package substrate 205. As shown in FIG. 5, the top surface of section 207 being elevated from the top surface of section 206 allows the arrangement of the different types of dies within the dimensions of the inner section of packaged electronic device 500.

The components of packaged electronic device 500 can be encapsulated with a mold compound 520. This encapsulation includes encapsulation of wires to the dies within packaged electronic device 500. Dies 510-1, 510-2, 510-3, and 510-4 can be coupled to package substrate 205 by a set of wires 513. Contacts 212 of package substrate 205 can allow components of packaged electronic device 500 to communicate, through package substrate 205, with electronic devices or systems exterior to packaged electronic device 500.

Package substrates having one or more elevated sections, as taught herein, are manufacturable with various processes. Such package substrates can provide for better reliability of the electronic dies positioned on the package substrates by reducing CTE mismatch of components of the packaged electronic device containing the package substrates. Such package substrates can provide better balance in package construction to reduce component warpage. Enhanced warpage performance (less warpage) can be attained by reducing excessive mold compound volume. It is expected that warpage reduction of around approximately 10% to approximately 20% can be attained with the package substrates taught herein, as compared to conventional packaged electronic devices using a package substrate such as package substrate 105 of FIG. 1. In addition, such package substrates having one or more elevated sections, as taught herein, can provide for shorter wire lengths providing better wire sweep characteristics. Packaged electronic devices using such package substrates are not limited to memory devices. Such package substrates can be used in other packaged electronic devices having multiple semiconductor dies.

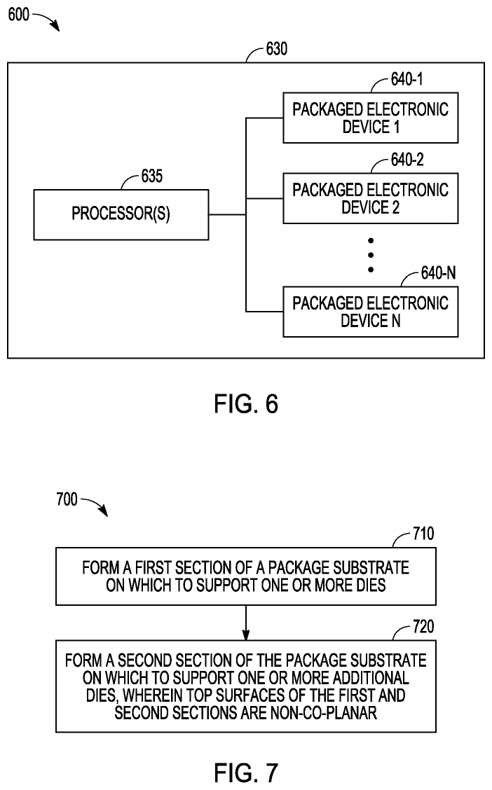

FIG. 6 is a block diagram of an embodiment of an example system 600 having one or more packaged electronic devices 640-1, 640-2 . . . 640-N. One or more of packaged electronic devices 640-1, 640-2 . . . 640-N can include a package substrate having one or more elevated sections, as taught herein. Packaged electronic devices 640-1, 640-2 . . . 640-N can operate in conjunction with one or more processors 635. Such operation can be facilitated using routing circuitry 645. One or more of the packaged electronic devices 640-1, 640-2 . . . 640-N can be memory devices. Such memory devices can include, but are not limited to, managed NAND memory devices. One or more of the packaged electronic devices 640-1, 640-2 . . . 640-N can include semiconductor dies different from memory dies or memory controllers that perform functions designed to operate according to system specifications for which for packaged electronic devices 640-1, 640-2 . . . 640-N are included in the given system. The one or more processors 635, packaged electronic devices 640-1, 640-2 . . . 640-N, and routing circuitry 645 can be implemented on a platform 630. Platform 630 can be, but is not limited to, a printed circuit board or a computer motherboard. Though routing circuitry 645 is shown as individual lines, routing circuitry 645 can be implemented as sets of patterned electrically conductive traces on platform 630. Routing circuitry 645 can be implemented as sets of bundled routing wires.

FIG. 7 is a flow diagram of features of an embodiment of an example method 700 of forming a structure for multiple dies on a common package substrate. At 710, a first section of a package substrate is formed to support one or more dies. The formed first section has a top surface and a bottom surface with one or more layers of material between the top surface and the bottom surface. The top surface of the first section can be referred to as a first top surface.

At 720, a second section of the package substrate is formed to support one or more additional dies. The second section can be formed having a top surface and the bottom surface of the first section, where the top surface of the second section can be referred to as a second top surface. The top surfaces of the first and sections are non-co-planar. The second section can be formed having one or more layers of material of the first section extending horizontally from the first section and structured between the second top surface and the bottom surface. The second section can be formed having one or more additional layers of material between the second top surface and a top of the one or more layers of material of the first section extending horizontally from the first section. The second top surface of the second section is at a level above the first top surface of the first section relative to the bottom surface. With respect to thickness of the two sections relative to the bottom surface, the second top surface is at a greater height above the bottom surface than a height of the first top surface above the bottom surface.

Variations of method 700 or methods similar to method 700 can include a number of different embodiments that may be combined depending on the application of such methods and/or the architecture of systems including an electronic device for which such methods are implemented. Such methods can include forming the second section having two or more layers with the two or more layers formed sequentially. Forming the two or more layers sequentially can include forming a laminate having layers containing reinforced fibers. Variations can include forming conductive routing circuits on the layers of the laminate.

Variations of method 700 or methods similar to method 700 can include attaching the one or more dies to the package substrate in the first section and attaching the one or more additional dies to the package substrate in the second section. The dies in the first section can include memory dies and the one or more additional dies in the second section can include memory dies, where the memory dies in the second section can be a different type of memory die than the memory dies in the first section. The material for the layers in the first section and the second section can be formed with different material compositions. The material can include a halogen-free bismaleimide triazine resin material or a metal-clad laminate with metal cladding of the metal-clad laminate patterned with conductive routing.

Variations of method 700 or methods similar to method 700 can include forming vias individually through the one or more layers of material of the first section and the one or more additional layers of material of the second section. Variations can include forming a ball grid array coupled to the vias at the bottom surface. Variations of method 700 or methods similar to method 700 can include forming one or more features associated with package substrates having multiple sections with at least one elevated section as discussed herein.

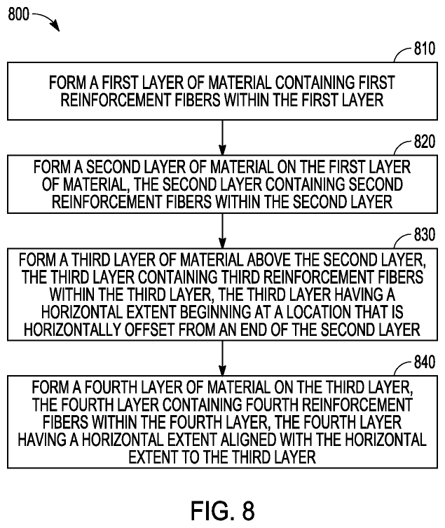

FIG. 8 is a flow diagram of features of an embodiment of an example method 800 of forming a structure for multiple dies on a common package substrate. A 810, a first layer of material is formed with the material containing first reinforcement fibers within the first layer. Vias, landing pads for the vias, and metallization routing associated with the first layer are formed. At 820, a second layer of material is formed on the first layer of material. The second layer is formed containing second reinforcement fibers within the second layer. Vias, landing pads for the vias, and metallization routing associated with the second layer are formed.

At 830, a third layer of material is formed above the second layer. The third layer is formed containing third reinforcement fibers within the third layer. Vias, landing pads for the vias, and metallization routing associated with the third layer are formed. The third layer is formed having a horizontal extent beginning at a location that is horizontally offset from an end of the second layer. The third layer is formed as a layer for the package substrate that is shorter in a horizontal length than the second layer. At 840, a fourth layer of material is formed on the third layer. The fourth layer is formed containing fourth reinforcement fibers within the fourth layer. Vias, landing pads for the vias, and metallization routing associated with the fourth layer are formed. The fourth layer is formed having a horizontal extent aligned with the horizontal extent of the third layer.

The formation of each of the first, second, third, and fourth layers can be performed individually for each layer. Once the individual layers are formed, the layers can be placed on each other with the landing pads aligned according to the design specification. Once the individual layers are combined with proper alignment, the layers can be binded together forming a single package substrate having two sections. The first section can include the binded first layer and second layer and the second section can include the binded first layer, second layer, third layer, and the fourth layer, where the top surface of the second section is elevated from the top surface of the first section relative to the bottom of the first layer. Alternatively, the single package substrate can be viewed as having a first section formed of the first and second layers and a second section formed of the third and fourth layers, where the top surface of the second section is elevated from the top surface of the first section relative to the bottom of the first layer. Methods similar to method 800 can be performed to form a single package substrate having a first section having one or more layers and a second section having two or more layers, with the second section having more layers than the first section and the top surface of the second section being elevated from the top surface of the first section relative to the bottom of the first section.

In various embodiments, a package substrate can comprise a first section and a second section. The first section is formed on which to support one or more dies. The first section can have a first top surface and a bottom surface with one or more layers of material between the first top surface and the bottom surface. The second section is formed on which to support one or more additional dies. The second section can have a second top surface and the bottom surface of the first section with the one or more layers of material of the first section extending horizontally from the first section and structured between the second top surface and the bottom surface. The second section has one or more additional layers of material between the second top surface and the one or more layers of material of the first section extending horizontally from the first section. The second top surface is at a level above the first top surface relative to the bottom surface.

Variations of such a package substrate and its features, as taught herein, can include a number of different embodiments and features that can be combined depending on the application of such package substrates, the format of such package substrates, and/or the architecture in which such package substrates are implemented. Variations of such package substrates can include the one or more layers of material having fiber reinforcement. The bottom surface of the package substrate can include contacts to electrically communicate with a device external to the package substrate.

Variations of such a package substrate and its features, as taught herein, can include the one or more layers of material and the one or more additional layers of material being structured such that the first section has fewer signal routing layers than signal routing layers of the second section. Variations can include the one or more layers of material including two layers of the material with conductive routing on a surface between the two layers and conductive vias through the two layers. The material for the two layers of the material can be selected from a number of different compositions. The two layers of the material can include a halogen-free bismaleimide triazine resin material. The two layers of the material can include a metal-clad laminate with metal cladding of the metal-clad laminate patterned with the conductive routing. The metal-clad laminate can be, but is not limited to, a copper-clad laminate.

In various embodiments, a packaged electronic device can comprise a first set of one or more dies, a second set of one or more additional dies, and a package substrate on which the one or more dies and the one or more additional dies are supported. The package substrate can include a first section and a second section. The first section is formed on which to support one or more dies. The first section can have a first top surface and a bottom surface with one or more layers of material between the first top surface and the bottom surface. The second section is structured on which to support one or more additional dies. The second section can have a second top surface and the bottom surface of the first section with the one or more layers of material of the first section extending horizontally from the first section and structured between the second top surface and the bottom surface. The second section has one or more additional layers of material between the second top surface and the one or more layers of material of the first section extending horizontally from the first section. The second top surface is at a level above the first top surface relative to the bottom surface. The package substrate has contacts to the bottom surface to electrically communicate with one or more devices external to the packaged electronic device.

Variations of such a packaged electronic device and its features, as taught herein, can include a number of different embodiments and features that can be combined depending on the application of such packaged electronic devices, the format of such packaged electronic devices, and/or the architecture in which such packaged electronic devices are implemented. Variations of such packaged electronic devices can include conductive vias coupled to the contacts, the conductive vias can include conductive vias extending through the first section and conductive vias extending through the second section. Variations of such packaged electronic devices can include the packaged electronic device having a mold compound encapsulating, within the packaged electronic device, the one or more dies, the one or more additional dies, and wires to provide communication to selected ones of the one or more dies and the one or more additional dies.

Variations of such packaged electronic devices can include a number of different arrangements of different types of electronic dies. Variations of such packaged electronic devices can include the first set including one or more volatile memory dies and the second set includes one or more non-volatile memory dies. The first set can include a controller die. The one or more volatile memory dies can include DRAM dies and the one or more non-volatile memory dies including NAND memory dies. Variations of such packaged electronic devices can include the first set including one or more non-volatile memory dies and the second set including a controller die. The one or more non-volatile memory dies can include NAND memory dies.

Variations of such packaged electronic devices can include a number of different material compositions for the material of the package substrate. The material can include a halogen-free bismaleimide triazine resin material. The material can include a metal-clad laminate with metal cladding of the metal-clad laminate patterned with conductive routing.

In various embodiments, a system can comprise one or more processors, routing circuitry, and one or more packaged electronic devices coupled to the one or more processors by the routing circuitry. At least one of the one or more packaged electronic devices includes a first set of one or more dies, a second set of one or more additional dies, and a package substrate on which the one or more dies and the one or more additional dies are supported. The package substrate can have a first section and a second section. The first section is formed on which to support one or more dies. The first section can have a first top surface and a bottom surface with one or more layers of material between the first top surface and the bottom surface. The second section is structured on which to support one or more additional dies. The second section can have a second top surface and the bottom surface of the first section with the one or more layers of material of the first section extending horizontally from the first section and structured between the second top surface and the bottom surface. The second section has one or more additional layers of material between the second top surface and the one or more layers of material of the first section extending horizontally from the first section. The second top surface is at a level above the first top surface relative to the bottom surface. The package substrate has contacts to the bottom surface to couple to the routing circuitry.

Variations of such a system and its features, as taught herein, can include a number of different embodiments and features that can be combined depending on the application of such systems, the format of such systems, and/or the architecture in which such systems are implemented. Variations of such systems can include the one or more layers of material having fiber reinforcement. The one or more layers of material and the one or more additional layers of material can be structured such that the first section has fewer signal routing layers than signal routing layers of the second section. The one or more layers of material can include two layers of the material with conductive routing on a surface between the two layers and conductive vias through the two layers.

Variations of such a system and its features, as taught herein, can include the at least one of the one or more packaged electronic devices having a mold compound encapsulating, within the packaged electronic device, the one or more dies, the one or more additional dies, and wires to provide communication to selected ones of the one or more dies and the one or more additional dies. Variations of such a system can include the first set having one or more volatile memory dies and a controller device, and the second set having one or more non-volatile memory dies. Variations of such a system can include the first set having one or more non-volatile memory dies and the second set having a controller die.

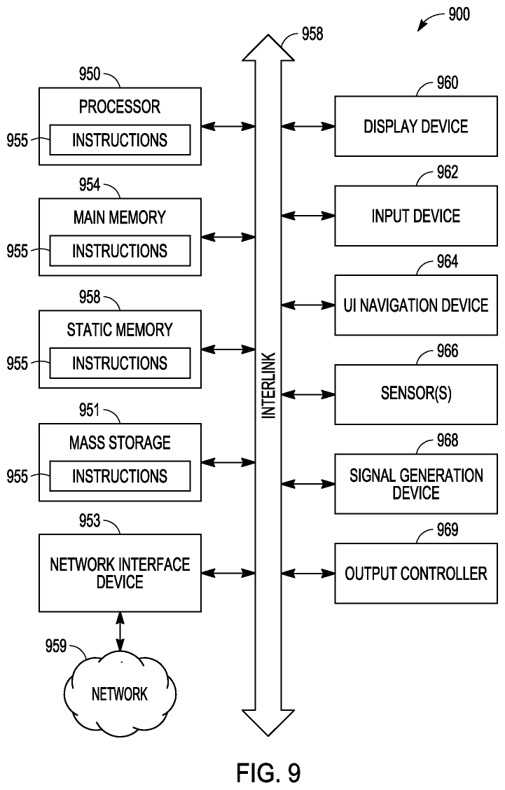

FIG. 9 illustrates a block diagram of an embodiment of an example machine 900 including one or more packaged electronic devices structured as discussed herein. In alternative embodiments, machine 900 can operate as a standalone device or can be connected (e.g., networked) to other machines. In a networked deployment, machine 900 can operate in the capacity of a server machine, a client machine, or both in server-client network environments. In an example, machine 900 can act as a peer machine in peer-to-peer (P2P) (or other distributed) network environment. Machine 900 can be a personal computer (PC), a tablet PC, a set-top box (STB), a personal digital assistant (PDA), a mobile telephone, a web appliance, an Internet of Things (IoT) device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more methodologies such as cloud computing, software as a service (SaaS), or other computer cluster configurations.

Examples, as described herein, can include, or can operate by, logic, components, devices, packages, or mechanisms. Circuitry is a collection (e.g., set) of circuits implemented in tangible entities that include hardware (e.g., simple circuits, gates, logic, conductive wiring routes, etc.). Circuitry membership can be flexible over time and underlying hardware variability. Circuitries include members that can, alone or in combination, perform specific tasks when operating. In an example, hardware of the circuitry can be immutably designed to carry out a specific operation (e.g., hardwired). In an example, the hardware of the circuitry can include variably connected physical components (e.g., execution units, transistors, simple circuits, etc.) including a computer readable medium physically modified (e.g., magnetically, electrically, moveable placement of invariant massed particles, etc.) to store instructions of the specific operation. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components can be used in more than one member of more than one circuitry.

The machine 900 can include a hardware processor 950 (e.g., a central processing unit (CPU), a graphics processing unit (GPU), a hardware processor core, or any combination thereof), a main memory 954, and a static memory 956, some or all of which can communicate with each other via an interlink 958 (e.g., bus). Machine 900 can further include a display device 960, an input device 962, which can be an alphanumeric input device (e.g., a keyboard), and a user interface (UI) navigation device 964 (e.g., a mouse). In an example, display device 960, input device 962, and UI navigation device 964 can be a touch screen display. Machine 900 can additionally include a mass storage device (e.g., drive unit) 951, a network interface device 953, a signal generation device 968, and one or more sensors 966, such as a global positioning system (GPS) sensor, compass, accelerometer, or other sensor. Machine 900 can include an output controller 969, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 900 can include one or more machine-readable media on which is stored one or more sets of data structures or instructions 955 (e.g., software, microcode, or other type of instructions) embodying or utilized by machine 900 to perform any one or more of the techniques or functions for which machine 900 is designed. The instructions 955 can reside, completely or at least partially, within main memory 954, within static memory 956, within mass storage device 951, or within hardware processor 950 during execution thereof by machine 900. In an example, one or any combination of hardware processor 950, main memory 954, static memory 956, or mass storage device 951 can constitute machine-readable media on which is stored one or more sets of data structures or instructions. Various ones of hardware processor 950, main memory 954, static memory 956, or mass storage device 951 can include one or more packaged electronic devices structured as discussed herein.

While an example machine-readable medium is illustrated as a single medium, the term “machine-readable medium” can include a single medium or multiple media (e.g., a centralized or distributed database, or associated caches and servers) configured to store instructions 955 or data. The term “machine-readable medium” can include any medium that is capable of storing instructions for execution by machine 900 and that cause machine 900 to perform any one or more of the techniques to which machine 900 is designed, or that is capable of storing data structures used by or associated with such instructions. Non-limiting machine-readable medium examples can include solid-state memories, optical media, and magnetic media. Specific examples of non-transitory machine-readable media can include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 955 (e.g., software, programs, an operating system (OS), etc.) or other data stored on mass storage device 951 can be accessed by main memory 954 for use by hardware processor 950. Main memory 954 (e.g., DRAM) is typically fast, but volatile, and thus a different type of storage than mass storage device 951 (e.g., a solid-state drive (SSD)), which is suitable for long-term storage, including while in an “off” condition. Instructions 955 or data in use by a user or machine 900 are typically loaded in main memory 954 for use by hardware processor 950. When main memory 954 is full, virtual space from mass storage device 951 can be allocated to supplement main memory 954; however, because mass storage device 951 is typically slower than main memory 954, and write speeds are typically at least twice as slow as read speeds, use of virtual memory can greatly reduce user experience due to storage device latency (in contrast to main memory 954, e.g., DRAM). Further, use of mass storage device 951 for virtual memory can greatly reduce the usable lifespan of mass storage device 951.

Storage devices optimized for mobile electronic devices, or mobile storage, traditionally include MultiMediaCard (MMC) solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 955 can further be transmitted or received over a network 959 using a transmission medium via signal generation device 968 or network interface device 953 utilizing any one of a number of transfer protocols (e.g., frame relay, Internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, signal generation device 968 or network interface device 953 can include one or more physical jacks (e.g., Ethernet, coaxial, or phone jacks) or one or more antennas to connect to network 959. In an example, signal generation device 968 or network interface device 953 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 900 or data to or from machine 900, and can include instrumentalities to propagate digital or analog communications signals to facilitate communication of such instructions, which instructions may be implemented by software or data.

The following example embodiments of methods and devices, in accordance with the teachings herein.

An example package substrate 1 can comprise: a first section on which to support one or more dies, the first section having a first top surface and a bottom surface with one or more layers of material between the first top surface and the bottom surface; and a second section on which to support one or more additional dies, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface.

An example package substrate 2 can include features of example package substrate 1 and can include the one or more layers of material including fiber reinforcement.

An example package substrate 3 can include features of any features of the preceding example package substrates and can include the bottom surface including contacts to electrically communicate with a device external to the package substrate.

An example package substrate 4 can include features of any of the preceding example package substrates and can include the one or more layers of material and the one or more additional layers of material being structured such that the first section has fewer signal routing layers than signal routing layers of the second section.

An example package substrate 5 can include features of any of the preceding example package substrates and can include the one or more layers of material to include two layers of the material with conductive routing on a surface between the two layers and conductive vias through the two layers.

An example package substrate 6 can include features of example package substrate 5 and any of the preceding example package substrates and can include the two layers of the material including a halogen-free bismaleimide triazine resin material.

An example package substrate 7 can include features of example package substrate 6 and any of the preceding example package substrates and can include the two layers of the material including a metal-clad laminate with metal cladding of the metal-clad laminate patterned with the conductive routing.

An example package substrate 8 can include features of example package substrate 7 and any of the preceding example package substrates and can include the metal-clad laminate being a copper-clad laminate.

In an example package substrate 9, any of the package substrates of example package substrates 1 to 8 may include package substrates incorporated into an electronic apparatus further comprising a host processor and a communication bus extending between the host processor and the package substrate.

In an example package substrate 10, any of the package substrates of example package substrates 1 to 9 may be modified to include any structure presented in another of example package substrate 1 to 9.

In an example package substrate 11, any apparatus associated with the package substrates of example package substrates 1 to 10 may further include a machine-readable storage device configured to store instructions as a physical state, wherein the instructions may be used to perform one or more operations of the apparatus.

In an example package substrate 12, any of the package substrates of example package substrates 1 to 11 may be formed in accordance with any of the below example methods 1 to 12.

An example packaged electronic device 1 can comprise: a first set of one or more dies; a second set of one or more additional dies; a package substrate on which the one or more dies and the one or more additional dies are supported, the package substrate including: a first section on which the one or more dies are supported, the first section having a first top surface and a bottom surface with one or more layers of material between the first top surface and the bottom surface; a second section on which the one or more additional dies are supported, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface; and contacts to the bottom surface to electrically communicate with one or more devices external to the packaged electronic device.

An example packaged electronic device 2 can include features of preceding example packaged electronic device 1 and can include conductive vias coupled to the contacts, the conductive vias including conductive vias extending through the first section and conductive vias extending through the second section.

An example packaged electronic device 3 can include features of any of the preceding example packaged electronic devices and can include a mold compound encapsulating, within the packaged electronic device, the one or more dies, the one or more additional dies, and wires to provide communication to selected ones of the one or more dies and the one or more additional dies.

An example packaged electronic device 4 can include features of any of the preceding example packaged electronic devices and can include the first set including one or more volatile memory dies and the second set including one or more non-volatile memory dies.

An example packaged electronic device 5 can include features of example packaged electronic device 4 and any features of the preceding example packaged electronic devices and can include the first set including a controller die.

An example packaged electronic device 6 can include features of any features of the preceding example packaged electronic devices and can include the first set including one or more non-volatile memory dies and the second set including a controller die.

An example packaged electronic device 7 can include features of any features of the preceding example packaged electronic devices and can include the material including a halogen-free bismaleimide triazine resin material or a metal-clad laminate with metal cladding of the metal-clad laminate patterned with conductive routing.

In an example packaged electronic device 8, any of the packaged electronic devices of example packaged electronic devices 1 to 7 may include packaged electronic devices incorporated into an electronic apparatus further comprising a host processor and a communication bus extending between the host processor and the packaged electronic device.

In an example packaged electronic device 9, any of the packaged electronic devices of example packaged electronic devices 1 to 8 may be modified to include any structure presented in another of example packaged electronic devices 1 to 8.

In an example packaged electronic device 10, any apparatus associated with the packaged electronic devices of example packaged electronic devices 1 to 7 may further include a machine-readable storage device configured to store instructions as a physical state, wherein the instructions may be used to perform one or more operations of the apparatus.

In an example packaged electronic device 11, any of the packaged electronic devices of example packaged electronic devices 1 to 10 may be formed in accordance with any of the methods of the below example methods 1 to 12.

An example system 1 can comprise: one or more processors; routing circuitry; one or more packaged electronic devices coupled to the one or more processors by the routing circuitry, at least one of the one or more packaged electronic devices including: a first set of one or more dies; a second set of one or more additional dies; a package substrate on which the one or more dies and the one or more additional dies are supported, the package substrate having: a first section on which the one or more dies are supported, the first section having a first top surface and a bottom surface with one or more layers of material between the first top surface and the bottom surface; a second section on which the one or more additional dies are supported, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface; and contacts to the bottom surface to couple to the routing circuitry.

An example system 2 can include features of preceding example system 1 and can include the one or more layers of material to include fiber reinforcement.

An example system 3 can include features of any of the preceding example systems and can include the one or more layers of material and the one or more additional layers of material being structured such that the first section has fewer signal routing layers than signal routing layers of the second section.

An example system 4 can include features of any of the preceding example systems and can include the one or more layers of material to include two layers of the material with conductive routing on a surface between the two layers and conductive vias through the two layers.

An example system 5 can include features of example system 4 and any features of the preceding example systems and can include the at least one of the one or more packaged electronic devices including a mold compound encapsulating, within the packaged electronic device, the one or more dies, the one or more additional dies, and wires to provide communication to selected ones of the one or more dies and the one or more additional dies.

An example system 6 can include features of any features of the preceding example systems and can include the first set including one or more volatile memory dies and a controller device, and the second set including one or more non-volatile memory dies.

An example system 7 can include features of any features of the preceding example systems and can include the first set including one or more non-volatile memory dies and the second set including a controller die.

In an example system 8, any of the systems of example systems 1 to 7 may include one or more systems incorporated into an electronic apparatus further comprising a host processor and a communication bus extending between the host processor and the one or more systems.

In an example system 9, any of the systems of example systems 1 to 8 may be modified to include any structure presented in another of example systems 1 to 8.

In an example system 10, any apparatus associated with the systems of example systems 1 to 9 may further include a machine-readable storage device configured to store instructions as a physical state, wherein the instructions may be used to perform one or more operations of the apparatus.

In an example system 11, any of the systems of example systems 1 to 10 may be formed in accordance with any of the methods of the below example methods 1 to 12.

An example method 1 can comprise: forming a first section of a package substrate on which to support one or more dies, the first section formed having a first top surface and a bottom surface with one or more layers of material between the first top surface and the bottom surface; and forming a second section of the package substrate on which to support one or more additional dies, the second section formed having a second top surface and the bottom surface of the first section with the one or more layers of material of the first section extending horizontally from the first section and structured between the second top surface and the bottom surface, the second section formed having one or more additional layers of material between the second top surface and the one or more layers of material of the first section extending horizontally from the first section, the second top surface at a level above the first top surface relative to the bottom surface.

An example method 2 can include features of example method 1 and can include forming the second section having two or more layers with the two or more layers formed sequentially.

An example method 3 can include features of any of the preceding example methods and can include forming the two or more layers sequentially to include forming a laminate having layers containing reinforced fibers.

An example method 4 can include features of example method 3 and any of the preceding example methods and can include forming conductive routing circuits on the layers of the laminate.

An example method 5 can include features of any of the preceding example methods and can include attaching the one or more dies to the package substrate in the first section and attaching the one or more additional dies to the package substrate in the second section.

An example method 6 can include features of any of the preceding example methods and can include the material including a halogen-free bismaleimide triazine resin material or a metal-clad laminate with metal cladding of the metal-clad laminate patterned with conductive routing.

An example method 7 can include features of any of the preceding example methods and can include forming vias individually through the one or more layers of material of the first section and the one or more additional layers of material of the second section.

An example method 8 can include features of any of the preceding example methods and can include forming a ball grid array coupled to the vias at the bottom surface.

In an example method 9, any of the example methods 1 to 8 may be performed in forming an electronic apparatus further comprising a host processor and a communication bus extending between the host processor and the memory device.

In an example method 10, any of the example methods 1 to 9 may be modified to include operations set forth in any other of example methods 1 to 9.

In an example method 11, any of the example methods 1 to 10 may be implemented at least in part through use of instructions stored as a physical state in one or more machine-readable storage devices.

An example method 12 can include features of any of the preceding example methods 1 to 11 and can include performing functions associated with any features of example package substrates 1 to 12, packaged electronic devices 1 to 11, and example systems 1 to 11.

An example machine-readable storage device 1 storing instructions, that when executed by one or more processors, cause a machine to perform operations, can comprise instructions to perform functions associated with any features of example package substrates 1 to 12, packaged electronic devices 1 to 11, and example systems 1 to 11 or perform methods associated with any features of example methods 1 to 12.

Although specific embodiments have been illustrated and described herein, it will be appreciated by those of ordinary skill in the art that any arrangement that is calculated to achieve the same purpose can be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A package substrate comprising:
a first section on which to support one or more dies, the first section having a first top surface and a bottom surface with one or more layers of material between the first top surface and the bottom surface; and
a second section on which to support one or more additional dies, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface.

2. The package substrate of claim 1, wherein the one or more layers of material include fiber reinforcement.

3. The package substrate of claim 1, wherein the bottom surface includes contacts to electrically communicate with a device external to the package substrate.

4. The package substrate of claim 1, wherein the one or more layers of material and the one or more additional layers of material are structured such that the first section has fewer signal routing layers than signal routing layers of the second section.

5. The package substrate of claim 1, wherein the one or more layers of material include two layers of the material with conductive routing on a surface between the two layers and conductive vias through the two layers.

6. The package substrate of claim 5, wherein the two layers of the material include a halogen-free bismaleimide triazine resin material.

7. The package substrate of claim 5, wherein the two layers of the material include a metal-clad laminate with metal cladding of the metal-clad laminate patterned with the conductive routing.

8. The package substrate of claim 7, wherein the metal-clad laminate is a copper-clad laminate.

9. A packaged electronic device comprising:
a first set of one or more dies;
a second set of one or more additional dies;
a package substrate on which the one or more dies and the one or more additional dies are supported, the package substrate including:
a first section on which the one or more dies are supported, the first section having a first top surface and a bottom surface with one or more layers of material between the first top surface and the bottom surface;
a second section on which the one or more additional dies are supported, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface; and
contacts to the bottom surface to electrically communicate with one or more devices external to the packaged electronic device.

10. The packaged electronic device of claim 9, wherein the packaged electronic device includes conductive vias coupled to the contacts, the conductive vias including conductive vias extending through the first section and conductive vias extending through the second section.

11. The packaged electronic device of claim 9, wherein the packaged electronic device includes a mold compound encapsulating, within the packaged electronic device, the one or more dies, the one or more additional dies, and wires to provide communication to selected ones of the one or more dies and the one or more additional dies.

12. The packaged electronic device of claim 9, wherein the first set includes one or more volatile memory dies and the second set includes one or more non-volatile memory dies.

13. The packaged electronic device of claim 12, wherein the first set includes a controller die.

14. The packaged electronic device of claim 9, wherein the first set includes one or more non-volatile memory dies and the second set includes a controller die.

15. The packaged electronic device of claim 9, wherein the material includes a halogen-free bismaleimide triazine resin material or a metal-clad laminate with metal cladding of the metal-clad laminate patterned with conductive routing.

16. A system comprising:
one or more processors;
routing circuitry;
one or more packaged electronic devices coupled to the one or more processors by the routing circuitry, at least one of the one or more packaged electronic devices including:
a first set of one or more dies;
a second set of one or more additional dies;
a package substrate on which the one or more dies and the one or more additional dies are supported, the package substrate having:
a first section on which the one or more dies are supported, the first section having a first top surface and a bottom surface with one or more layers of material between the first top surface and the bottom surface;
a second section on which the one or more additional dies are supported, the second section having a second top surface and the bottom surface of the first section with the one or more layers of material of the first section extending horizontally from the first section and structured between the second top surface and the bottom surface, the second section having one or more additional layers of material between the second top surface and the one or more layers of material of the first section extending horizontally from the first section, the second top surface at a level above the first top surface relative to the bottom surface; and
contacts to the bottom surface to couple to the routing circuitry.

17. The system of claim 16, wherein the one or more layers of material and the one or more additional layers of material are structured such that the first section has fewer signal routing layers than signal routing layers of the second section.

18. The system of claim 16, wherein the one or more layers of material include two layers of the material with conductive routing on a surface between the two layers and conductive vias through the two layers.

19. The system of claim 16, wherein the at least one of the one or more packaged electronic devices includes a mold compound encapsulating, within the packaged electronic device, the one or more dies, the one or more additional dies, and wires to provide communication to selected ones of the one or more dies and the one or more additional dies.

20. The system of claim 16, wherein the first set includes one or more volatile memory dies and a controller device, and the second set includes one or more non-volatile memory dies or the first set includes one or more non-volatile memory dies and the second set includes a controller die.
